(19) United States
(12) Patent Application Publication
(10) Pub. No.: US 2025/0331337 A1
(43) Pub. Date: Oct. 23, 2025

(54) SHAPED MICRO REFLECTOR PRINTING PROCESS FOR SIDE-FIRE MICRO LIGHT-EMITTING DIODE DISPLAYS

(71) Applicant: GM GLOBAL TECHNOLOGY OPERATIONS LLC, DETROIT, MI (US)

(72) Inventors: Jonglee Park, Novi, MI (US); Julien P. Mourou, Bloomfield Hills, MI (US); Reza Chaji, Kitchener (CA); Chang-Ho Park, Burlington (CA)

(21) Appl. No.: 18/641,706

(22) Filed: Apr. 22, 2024

(51) Int. Cl. H01L 33/46; H01L 25/075

(52) U.S. Cl. CPC H10H 20/841; H01L 25/0753; H10H 20/034

(57) ABSTRACT

Aspects of the disclosure include display units having shaped micro reflectors with integrated side-fire micro light-emitting diodes (micro LEDs) which can be stand-alone or laminated into glass or laminated glass assemblies (e.g., a glass panel of a vehicle). An exemplary display unit includes a side-fire micro light-emitting diode on a surface of a display substrate. The side-fire micro light-emitting diode is coated with a first reflective layer such that light is emitted from an uncoated sidewall. The display unit includes a shaped micro reflector coated with a second reflective layer on the display substrate. The shaped micro reflector includes a tapered sidewall positioned to redirect, via reflection against the second reflective layer, light from the uncoated sidewall of the side-fire micro light-emitting diode from an emitted angle to a reflection angle. The second reflective layer is formed directly on opposite sidewalls and a bottommost surface of the shaped micro reflector.

### INTRODUCTION

The subject disclosure relates to display technologies, and particularly to a shaped micro reflector printing process for side-fire micro light-emitting diode (micro LED) displays.

Light-emitting diodes (LEDs) have revolutionized the field of display technology with their efficient and versatile capabilities. LEDs are semiconductor devices that emit light when an electric current is passed through them. LED displays can be monochrome or multi-colored displays, and depending on the underlying architecture, generally leverage an active layer interposed between two doped layers (e.g., an n-type semiconductor layer and a p-type semiconductor layer) and the application of a voltage between the two doped layers to generate light. Voltage causes electrons to be injected into the active layer, which recombine within the active layer to release photons. When compared to traditional incandescent bulbs, LEDs can be driven at relatively low voltages while emitting lower levels of heat, providing comparatively high energy efficiencies. LEDs can be manufactured in a range of display and screen types, such as, for example, in head up displays (HUDs), in-plane displays (e.g., an in-plane communication device laminated in or on a vehicle window to communicate with users inside or outside the vehicle), smart glass applications, and general device displays.

Early generation LED displays were somewhat simple devices configured to display a limited variety of static images, signs, symbols, and/or messages as needed, and are usually fabricated by arranging the LED(s) to feed a lightbar via a collimating optic (i.e., a collimator). Light from the lightbar is mixed using a mixing region or homogenizing region and ultimately displayed in a display region. LED technology has rapidly evolved, however, and displays can now leverage a dense array of micro LEDs to drive sophisticated multipixel displays.

Micro LEDs are tiny individual light-emitting diodes, typically less than 100 micrometers in size, that can be fabricated using advanced semiconductor manufacturing techniques. Micro LED displays offer numerous advantages over prior-generation LED display systems, such as a higher brightness, improved color accuracy, greater energy efficiency, and other enhanced performance characteristics. These attributes make micro LED displays ideal for automotive applications (e.g., in a vehicle's in-plane communication system), where visibility, clarity, and power efficiency are highly desirable.

### SUMMARY

In one exemplary embodiment a method can include forming a cartridge by forming a release layer on a substrate, forming a shaped micro reflector on the release layer, the shaped micro reflector having tapered sidewalls, and forming a reflective layer over the shaped micro reflector and the release layer. The method can include bonding the cartridge to a display substrate using a bonding layer positioned between the reflective layer and the display substrate. The method can include removing the release layer of the cartridge, thereby separating the substrate from the display substrate.

In some embodiments, the release layer includes at least one of an ultraviolet (UV) curable material and a thermally curable material.

In some embodiments, the reflective layer is conformally deposited over the shaped micro reflector and the release layer. In some embodiments, the reflective layer is conformally deposited to a thickness of between 5 nanometers and 3 microns.

In some embodiments, the cartridge is flipped prior to bonding to the display substrate.

In some embodiments, removing the release layer includes at least one of exposing the release layer to UV radiation and exposing the release layer to thermal energy.

In another exemplary embodiment a display unit includes a side-fire micro light-emitting diode on a surface of a display substrate. The side-fire micro light-emitting diode is coated with a first reflective layer such that light is emitted from an uncoated sidewall. The display unit includes a shaped micro reflector coated with a second reflective layer. The shaped micro reflector is adjacent to the side-fire micro light-emitting diode and includes a tapered sidewall positioned to redirect, via reflection against the second reflective layer, light from the uncoated sidewall of the side-fire micro light-emitting diode from an emitted angle to a reflection angle.

In some embodiments, the tapered sidewall has a degree of taper as measured with respect to the surface of the display substrate of between −90 and 90 degrees, where zero degrees of taper is orthogonal to the surface of the display substrate.

In some embodiments, the shaped micro reflector has a taper of approximately 30 to 60 degrees.

In some embodiments, a topmost surface of the shaped micro reflector is not coated with the second reflective layer.

In some embodiments, the uncoated sidewall of the side-fire micro light-emitting diode directly faces the tapered sidewall of the shaped micro reflector.

In some embodiments, a tracer is formed on the display substrate. In some embodiments, the shaped micro reflector and second reflective layer are formed on the tracer.

In yet another exemplary embodiment a method can include forming a side-fire micro light-emitting diode on a surface of a display substrate. The side-fire micro light-emitting diode is coated with a first reflective layer such that light is emitted from an uncoated sidewall. The method includes forming a shaped micro reflector coated with a second reflective layer on the display substrate. The shaped micro reflector is adjacent to the side-fire micro light-emitting diode and includes a tapered sidewall positioned to redirect, via reflection against the second reflective layer, light from the uncoated sidewall of the side-fire micro light-emitting diode from an emitted angle to a reflection angle.

In some embodiments, the tapered sidewall has a degree of taper as measured with respect to the surface of the display substrate of between −90 and 90 degrees, where zero degrees of taper is orthogonal to the surface of the display substrate.

In some embodiments, the shaped micro reflector has a taper of approximately 30 to 60 degrees.

In some embodiments, a topmost surface of the shaped micro reflector is not coated with the second reflective layer.

In some embodiments, the uncoated sidewall of the side-fire micro light-emitting diode directly faces the tapered sidewall of the shaped micro reflector.

In some embodiments, a tracer is formed on the display substrate. In some embodiments, the shaped micro reflector and second reflective layer are formed on the tracer.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is a vehicle configured in accordance with one or more embodiments;

FIG. 2A is a cross-sectional view of a display unit of a display in accordance with one or more embodiments;

FIG. 2B is a cross-sectional view of a portion of the side-fire micro LED of FIG. 2A in accordance with one or more embodiments;

FIG. 3A is a cross-sectional view of a cartridge during a process for manufacturing a display unit in accordance with one or more embodiments;

FIG. 3B is a cross-sectional view of the cartridge of FIG. 3A during a process for manufacturing a display unit in accordance with one or more embodiments;

FIG. 3C is a cross-sectional view of a display unit during a process for manufacturing the display unit in accordance with one or more embodiments;

FIG. 3D is a cross-sectional view of a plurality of display units during a process for manufacturing a display in accordance with one or more embodiments;

FIG. 4 is a top-down view of a display unit of a display in accordance with one or more embodiments;

FIG. 5. is a computer system according to one or more embodiments;

FIG. 6 is a flowchart in accordance with one or more embodiments; and

FIG. 7 is a flowchart in accordance with one or more embodiments.

### DETAILED DESCRIPTION

The following description is merely exemplary in nature and is not intended to limit the present disclosure, its application or uses. It should be understood that throughout the drawings, corresponding reference numerals indicate like or corresponding parts and features. As used herein, the term module refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

Micro light-emitting diodes (micro LEDs) have largely replaced early generation LEDs for display applications. The conventional way to drive the micro LEDs in a display system is to use a thin film transistor (TFT) backplane installed on an underlying substrate. The TFT backplane acts as a switching element that controls the current flowing through each individual LED pixel in the display. Accordingly, to integrate working micro LEDs into a glass laminate assembly of a vehicle (e.g., a front windshield, a passenger window, etc.), the TFT backplane must be laminated alongside the micro LEDs between the inner and outer glass layers of the glass laminate assembly.

There are some challenges, however, in integrating micro-LED based displays in a range of applications. For example, in automobile lighting systems such as tail lamps and the center high mount stop lamp (CHMSL), the underlying lighting systems, housing, and/or optic systems are normally placed in the vehicle's body. A micro-led based lighting system therefore requires some space to package the lighting module (micro LEDs, TFT backplane, etc.), adding weight and somewhat increasing the difficulty of the laminate assembly process. Complicating matters further, micro LEDs naturally direct most of their emitted light in a direction orthogonal to a major surface of the underlying substrate (the substrate upon which the micro LEDs are placed). In applications such as head up displays (HUDs), the direction of emitted light does not necessarily align with the anticipated viewing direction, such as with the eye level of a driver and/or passenger. As a result, much of the emitted light is wasted.

This disclosure introduces a way to fabricate a shaped micro reflector on a micro LED display. The shaped micro reflector can be positioned adjacent to a side-fire micro LED to redirect emitted light from the LED to any desirable reflection angle, thereby increasing the relative proportion of emitted light that is actually observed (that is, emitted along a viewing angle). Micro LED displays having shaped micro reflectors and side-fire micro LEDs configured in this manner can operate at a lower driving voltage while achieving the same observable brightness due to the increase in the proportion of emitted light that is redirected along useful paths. Moreover, by laminating a combination of side-fire micro LEDs and micro reflector arrays into glass layer for vehicle windows, the conventional exterior lighting module package can be removed, reducing vehicle weight.

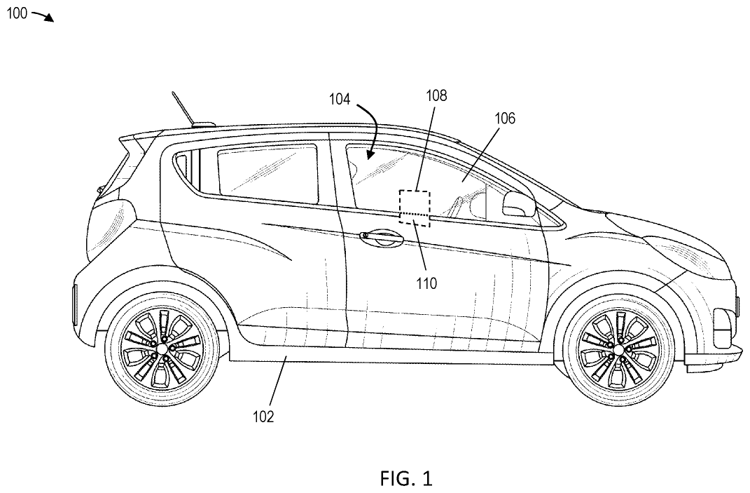

A vehicle, in accordance with an exemplary embodiment, is indicated generally at 100 in FIG. 1. Vehicle 100 is shown in the form of an automobile having a body 102. Body 102 includes a passenger compartment 104 within which are arranged a steering wheel, front seats, and rear passenger seats (not separately indicated). Body 102 also includes a number of glass or glass laminate assemblies, such as, for example a laminated glass panel 106. The particular laminated glass panel 106 (here, the front passenger window) is emphasized only for ease of illustration and discussion. It should be understood that any aspect of the present disclosure can be applied to any of the glass and glass laminate assemblies in the vehicle 100, including, for example, the front windshield (e.g., HUD applications), any of the driver and passenger door windows (front and rear), the rear glass panel, a sunroof/moonroof, etc. In short, the location, size, arrangement, etc., of the laminated glass panel 106 is not meant to be particularly limited, and all such configurations are within the contemplated scope of this disclosure. As will be detailed herein, the laminated glass panel 106 includes a display 108. The display 108 (also referred to as a lighting profile controllable micro LED panel) includes one or more side-fire micro LEDs cointegrated with one or more shaped micro reflectors. The side-fire micro LEDs, shaped micro reflectors, and methods of manufacturing the same are discussed in greater detail below. In some embodiments, a portion 110 of the display 108 is hidden within the body 102 (as shown).

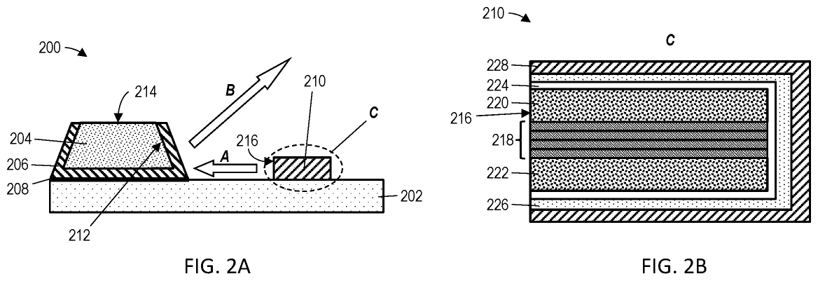

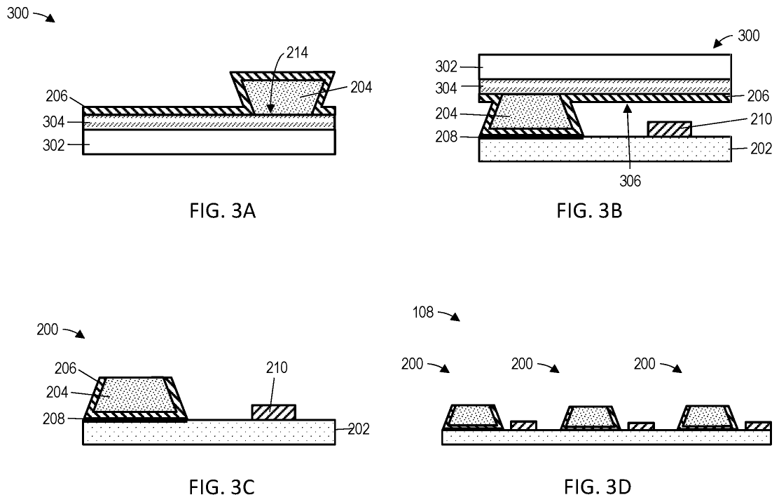

FIG. 2A illustrates a cross-sectional view of a display unit 200 of a display (e.g., the display 108 shown in FIG. 1) in accordance with one or more embodiments. As shown in FIG. 2A, the display unit 200 includes a display substrate 202, a shaped micro reflector 204 coated with a reflective layer 206, a bonding layer 208 between the reflective layer 206 and the display substrate 202, and a side-fire micro LED 210 adjacent to the shaped micro reflector 204 and on the display substrate 202. While only a single display unit 200 is shown for ease of illustration and discussion, it should be understood that a display can include any number of display units 200 (refer to FIG. 3D).

The display substrate 202 can be made of a range of suitable materials and will vary depending on the needs of the respective application (e.g., desired structural, thermal, and optical properties, etc.). In some embodiments, for example, the display substrate 202 is a glass substrate. In some embodiments, the display substrate is made of glass, polycarbonate (PC) materials, acrylic materials such as polymethyl methacrylate (PMMA), thermoplastics such as thermoplastic polyurethane (TPU), glass-ceramic materials, such as soda-lime-silica glass-ceramics, aluminosilicate glass-ceramics, lithium aluminosilicate glass-ceramics, spinel glass-ceramics, and beta-quartz glass-ceramics, and combinations thereof.

The shaped micro reflector 204 can include polymer materials such as PC and PMMA, although other polymers are within the contemplated scope of this disclosure. In some embodiments, the shaped micro reflector 204 is formed having a tapered sidewall 212 having any desired degree of taper. As will be discussed in further detail herein, the degree of taper of the shaped micro reflector 204 redirects, via reflection against the reflective layer 206, an emitted angle A of light from the side-fire micro LED 210 to a reflection angle B. Thus, by changing the degree of taper of the shaped micro reflector 204, the reflection angle B can be tuned as desired. In some embodiments, the degree of taper is between −90 and 90 degrees, as measured with respect to the surface of the display substrate 202, where zero degrees of taper is orthogonal to the surface of the display substrate 202. In some embodiments, the degree of taper is between −45 and 45 degrees. In some embodiments, the degree of taper is between −30 and 30 degrees. In some embodiments, the shaped micro reflector 204 has a positive taper between 0 and 90 degrees (e.g., an acute angle). In some embodiments, the shaped micro reflector 204 has a positive taper between 0 and 60 degrees. In some embodiments, the shaped micro reflector 204 has a taper between 0 and −90 degrees (e.g., an obtuse angle, or a so-called negative taper with respect to a direction normal to the underlying surface). In some embodiments, the shaped micro reflector 204 has a positive taper between 0 and −60 degrees. For example, as shown in FIG. 2A, the shaped micro reflector 204 has a taper of approximately −15 degrees.

As shown in FIG. 2A, the shaped micro reflector 204 can be coated with the reflective layer 206. In some embodiments, the reflective layer 206 is coated along three surfaces (e.g., opposite sidewalls and a bottommost surface in contact with the bonding layer 208), while a topmost surface 214 of the shaped micro reflector 204 is exposed (as shown). In some embodiments, the reflective layer 206 is conformally formed on the shaped micro reflector 204, thereby having the same taper as the shaped micro reflector 204. As used herein, the term “conformal” (e.g., a conformal layer or a layer conformally formed, etc.) means that a thickness of the respective layer is substantially the same on all surfaces upon which the respective layer is formed or deposited, or that the thickness variation is less than 15% of the nominal thickness of the respective layer.

In some embodiments, the reflective layer 206 includes a metal material, such as, for example, silver, gold, or copper, although other metals and conductive non-metals are within the contemplated scope of this disclosure. In some embodiments, the reflective layer 206 includes a dielectric stack having one or more dielectric layers (not separately shown). The dielectric layers can include, for example, silicon dioxide (SiO₂), silicon nitride (Si₃N₄), polyimide, benzocyclobutene (BCB), spin-on glass (SOG), aluminum oxide (Al₂O₃), hafnium oxide (HfO₂), and combinations thereof, although other dielectrics are within the contemplated scope of this disclosure.

In some embodiments, the bonding layer 208 is positioned between the reflective layer 206 and the display substrate 202. In this manner, the reflective layer 206 and shaped micro reflector 204 are bonded to the display substrate 202 via the bonding layer 208. While not meant to be particularly limited, the bonding layer 208 can be made of a plastic interlayer material(s), such as a polyvinyl butyral (PVB) film.

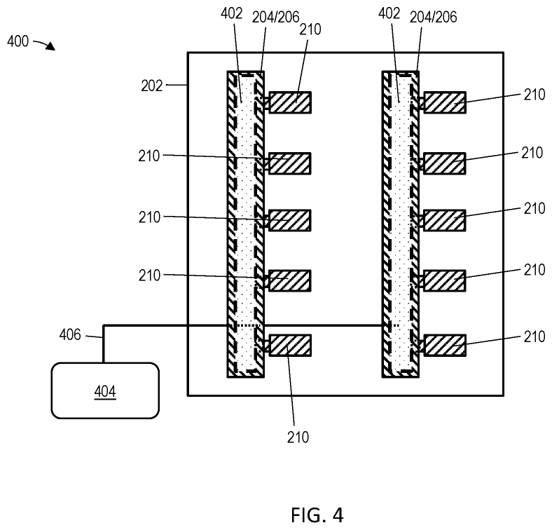

In some embodiments, the side-fire micro LED 210 is electrically coupled to the display substrate 202. In some embodiments, the side-fire micro LED 210 is powered via a driving current received though the display substrate 202 (refer to FIG. 4). In some embodiments, the side-fire micro LED 210 includes a single LED element. In some embodiments, the side-fire micro LED 210 includes a plurality of micro LED elements, such as, for example, a red micro LED element, a green micro LED element, and/or a blue micro LED element (not separately shown). The side-fire micro LED 210 can be formed from a range of suitable material(s), such as, for example, semiconductor materials (e.g., silicon, gallium nitride, indium gallium nitride, etc.) and sapphire, depending on the desired emission color of the respective micro LED. For example, gallium nitride (GaN) for blue LEDs, indium gallium nitride (InGaN) for green LEDs, and aluminum gallium indium phosphide (AlGaInP) for red LEDs.

In some embodiments, the side-fire micro LED 210 is coated such that the side-fire micro LED 210 emits a directional light A (also referred to as an emitted light) from a sidewall 216 of the side-fire micro LED 210 directly facing the reflective layer 206 on the shaped micro reflector 204. The coating layers of the side-fire micro LED 210 are discussed in greater detail with respect to FIG. 2B.

FIG. 2B illustrates a cross-sectional view of a portion C of the side-fire micro LED 210 of FIG. 2A in accordance with one or more embodiments. As shown in FIG. 2B, in some embodiments, the side-fire micro LED 210 includes several stacked multi-quantum well (MQW) layers 218 between a p-doped layer 220 and an n-doped layer 222. The side-fire micro LED 210 is shown having four MQW layers 218, although any number of MQW layers are within the contemplated scope of this disclosure.

The MQW layers 218 can include alternating layers of semiconductor materials defining a series of quantum wells and barriers. Quantum well materials can include, for example, indium gallium nitride (InGaN), aluminum gallium indium phosphide (AlGaInP), gallium indium phosphide (GaInP), gallium arsenide phosphide (GaAsP), gallium indium arsenide phosphide (GaInAsP), gallium arsenide (GaAs), indium gallium arsenide (InGaAs), and aluminum gallium arsenide (AlGaAs). Barrier materials can include, for example, gallium nitride (GaN), aluminum gallium nitride (AlGaN), aluminum gallium indium phosphide (AlGaInP), aluminum indium phosphide (AlInP), gallium indium phosphide (GaInP), AlGaAs, and aluminum arsenide (AlAs).

The p-doped layer 220 can include, for example, magnesium (Mg), zinc (Zn), carbon (C), and/or beryllium (Be), although other materials are within the contemplated scope of this disclosure. The n-doped layer 222 can include, for example, silicon (Si), germanium (Ge), and/or tellurium (Te), although other materials are within the contemplated scope of this disclosure.

In some embodiments, the side-fire micro LED 210 includes an optic layer 224 in contact with both the p-doped layer 220 and the n-doped layer 222. In some embodiments, the optic layer 224 is a conformal layer in further contact with the MQW layers 218 (as shown). Materials for the optic layer 224 can include, for example, distributed Bragg reflector (DBR) layers, such as alternating layers of semiconductor and/or dielectric materials with different refractive indices, including GaN/AlGaN, GaAs/AlGaAs, and SiO₂/TiO₂, transparent conductive oxides (TCOs), such as indium tin oxide (ITO), zinc oxide (ZnO), and aluminum-doped zinc oxide (AZO).

In some embodiments, the side-fire micro LED 210 includes a dielectric layer 226 between the optic layer 224 and a reflective layer 228. The dielectric layer 226 can include, for example, silicon dioxide, silicon nitride, polyimide, benzocyclobutene, spin-on glass, aluminum oxide, hafnium oxide, and combinations thereof, although other dielectrics are within the contemplated scope of this disclosure. Materials for the reflective layer 228 can include, for example, DBR layers, such as alternating layers of semiconductor and/or dielectric materials with different refractive indices, including GaN/AlGaN, GaAs/AlGaAs, and SiO₂/TiO₂, transparent conductive oxides (TCOs), such as indium tin oxide (ITO), zinc oxide (ZnO), and aluminum-doped zinc oxide (AZO), dielectric mirror (DL) layers, such as alternating layers of dielectric materials with different refractive indices, including SiO₂/Si₃N₄, SiO₂/TiO₂, and SiO₂/HfO₂, anti-reflection coatings (ARCs), such as SiO₂, Si₃N₄, TiO₂, and MgF₂, and combinations thereof. Observe that the reflective layer 228 is positioned to expose the sidewall 216, thereby allowing light emitted from the side-fire micro LED 210 to be directed solely from the sidewall 216 (light contacting other surfaces of the side-fire micro LED 210 is directed back to the sidewall 216 due to internal reflection of the reflective layer 228).

FIG. 3A illustrates a cross-sectional view of a cartridge 300 during a process for manufacturing a display unit (e.g., the display unit 200 of FIG. 2A) in accordance with one or more embodiments. As shown in FIG. 3A, the cartridge 300 includes a substrate 302. While not meant to be particularly limited, the substrate 302 can include, for example, glass, sapphire, semiconductor materials, dielectrics, and combinations thereof. In some embodiments, the substrate 302 is a glass substrate.

In some embodiments, a release layer 304 is formed on the substrate 302. In some embodiments, the release layer 304 is an ultraviolet (UV) and/or thermally curable material, such that exposure to UV light and/or thermal energy (e.g., laser) causes the release layer 304 to separate from the substrate 302. In some embodiments, the release layer 304 is made of a material selected such that, upon receiving UV radiation and/or thermal energy exposure, a bond strength between the release layer 304 and the substrate 302 is lowered such that removal of the release layer 304 is relatively easier than prior to the UV radiation and/or thermal energy exposure. Example materials can include, for example, photoresists such as PMMA, polymer release layers such as polyvinyl alcohol (PVA), polyacrylic acid (PAA), and polystyrene (PS) layers, sacrificial oxide layers such as silicon dioxide and aluminum oxide, metallic release layers such as aluminum, titanium, and chromium, organic light transfer layers such as polydimethylsiloxane (PDMS), and laser release layers such as polymer films with light-absorbing dyes and/or nanoparticles, or combinations thereof.

In some embodiments, the shaped micro reflector 204 (refer to FIG. 2A) is formed on the release layer 304. In some embodiments, the shaped micro reflector 204 is formed using a laser etching process, although other techniques, such as chemical vapor deposition (CVD) and electroplating are within the contemplated scope of this disclosure.

In some embodiments, the reflective layer 206 (refer to FIG. 2A) is formed on the shaped micro reflector 204. In some embodiments, the reflective layer 206 is conformally deposited over the shaped micro reflector 204 and the release layer 304 using, for example, CVD, plasma-enhanced CVD (PECVD), ultrahigh vacuum CVD (UHVCVD), rapid thermal CVD (RTCVD), metalorganic CVD (MOCVD), low-pressure CVD (LPCVD), limited reaction processing CVD (LRPCVD), atomic layer deposition (ALD), physical vapor deposition (PVD), chemical solution deposition, molecular beam epitaxy (MBE), or other like process in combination with wet or dry etch processes. In some embodiments, the reflective layer 206 is deposited to a thickness of between 5 nanometers and 3 microns, although other thicknesses are within the contemplated scope of this disclosure. Observe that the topmost surface 214 (refer to FIG. 2A) of the shaped micro reflector 204 is not coated with the reflective layer 206 due to the reflective layer 206 being formed on the release layer 304. The exposed topmost surface 214 serves as a physical signature for the manufacturing process described herein. Observe that, in this intermediate configuration (pre-cartridge flip, refer to FIG. 3B), the topmost surface 214 is a bottommost surface of the shaped micro reflector 204.

FIG. 3B illustrates a cross-sectional view of the cartridge 300 of FIG. 3A during a process for manufacturing a display unit (e.g., the display unit 200 of FIG. 2A) in accordance with one or more embodiments. As shown in FIG. 3B, the cartridge 300 is flipped and bonded to the display substrate 202 (refer to FIG. 2A). In some embodiments, the reflective layer 206 is bonded to the display substrate 202 via the bonding layer 208. The bonding layer 208 can be formed on the reflective layer 206, the display substrate 202, or both. In some embodiments, the reflective layer 206 and the display substrate 202 can be pressed together to set the bonding layer 208.

FIG. 3C illustrates a cross-sectional view of a display unit (e.g., the display unit 200 of FIG. 2A) during a process for manufacturing the display unit in accordance with one or more embodiments. As shown in FIG. 3C, the release layer 304 and the substrate 302 of the cartridge 300 (refer to FIG. 3B) can be removed to define the display unit 200. In some embodiments, the release layer 304 and/or the substrate 302 are exposed to UV light and/or to thermal energy for release, as discussed previously. In some embodiments, removal of the release layer 304 also results in removal of portions 306 of the reflective layer 206 (as shown).

FIG. 3D illustrates a cross-sectional view of a plurality of display units 200 during a process for manufacturing a display (e.g., display 108 of FIG. 1) in accordance with one or more embodiments. As shown in FIG. 3D, the manufacturing process described with respect to FIGS. 3A, 3B, and 3C can be repeated, concurrently and/or sequentially, to provide a display 108 having any umber of display units 200. The display 108 is shown in FIG. 3D having three display units 200 for convenience only and it should be understood that the display 108 can include any number of display units 200 as desired, and all such configurations are within the contemplated scope of this disclosure.

While not separately shown, the display unit(s) 200 can be incorporated within a glass panel or laminated glass panel of a display (e.g., the display 108 shown in FIG. 1) using known limitation processes. In some embodiments, one or more display units 200 are laminated between an outer glass layer (also referred to as outer glass ply) and an inner glass layer (also referred to as an inner glass ply) of a laminated panel (not separately shown). In some embodiments, the display substrate 202 is one or both of the outer glass layer and inner glass layer. The laminated glass panel can include one or more additional layers above and/or below the outer glass layer and/or the inner glass layer. For example, the laminated glass panel can include one or more layers for anti-reflection, solar comfort, auto-tinting, and/or general appearance.

FIG. 4 illustrates a top-down view of a display unit 400 of a display (e.g., the display 108 shown in FIG. 1) in accordance with one or more embodiments. The display unit 400 can be formed in a similar manner as the display unit 200 discussed with respect to FIGS. 3A-3D, except that the display unit 400 can include one or more side-fire micro LEDs 210 coupled to one or more tracers 402 (a tracer can also be referred to as a backplane) on the display substrate 202. In some embodiments, the shaped micro reflector 204 and reflective layer 206 are formed on the tracer 402, thereby allowing the display unit 400 to maintain transparency for applications such as an in-plane display in or on glass where transparency is required or desired. Notably, positioning the shaped micro reflector 204 and reflective layer 206 on the tracer 402 reduces light transmittance drop from the opaque reflector structure (the shaped micro reflector 204 and reflective layer 206).

As shown, 10 side-fire micro LEDs 210 are coupled to the tracer(s) 402 in a 2×5 configuration, although any number of side-fire micro LEDs 210 can be coupled to the tracer(s) 402 in any desirable configuration, and all such configurations are within the contemplated scope of this disclosure. In some embodiments, the tracers 402 are communicatively coupled to a controller 404 via electrical connections 406 (wires, driving circuits, bus lines, etc.).

In some embodiments, the controller 404 is configured to individually direct the tracer(s) 402 to selectively activate their respective side-fire micro LEDs 210, thereby generating a desired image or graphic. In some embodiments, for example, the controller 404 and/or tracers 402 can control a respective one of the side-fire micro LEDs 210 by selectively passing a driving voltage to the respective side-fire micro LED 210. While not meant to be particularly limited, in some embodiments, the controller 220 can include, for example, an Electronic Control Unit (ECU) of the vehicle 100.

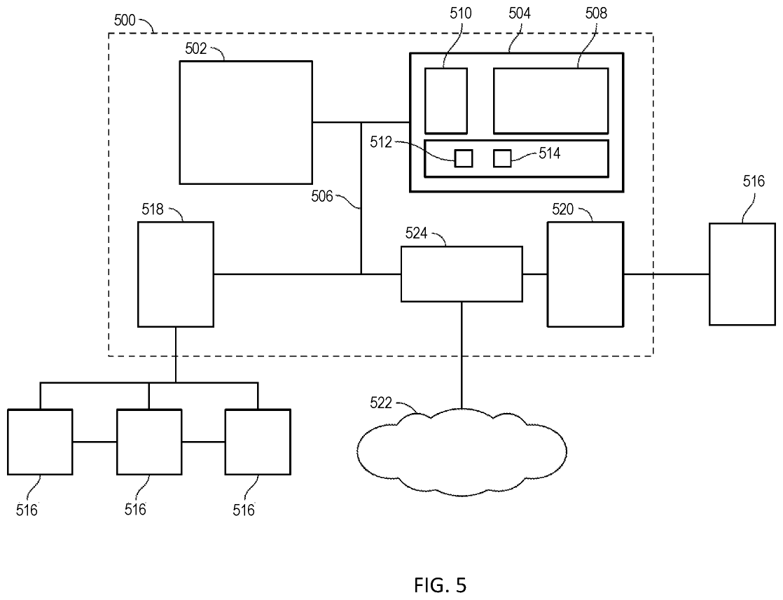

FIG. 5 illustrates aspects of an embodiment of a computer system 500 that can perform various aspects of embodiments described herein. In some embodiments, the computer system 500 can be incorporated within or in combination with a display (e.g., the display 108 of FIG. 1), a driving circuit (e.g., tracers 402 of FIG. 4), and/or a controller (e.g., controller 404 of FIG. 4). The computer system 500 includes at least one processing device 502, which generally includes one or more processors for performing a variety of functions, such as, for example, controlling driving voltages to one or more of the side-fire micro LEDs 210 of the display 108. More specifically, the computer system 500 can include the logic necessary to direct voltages to activate or deactivate (turn on or off) the individual micro LEDs 210 or any subset of the micro LEDs 210 of the display 108.

Components of the computer system 500 include the processing device 502 (such as one or more processors or processing units), a system memory 504, and a bus 506 that couples various system components including the system memory 504 to the processing device 502. The system memory 504 may include a variety of computer system readable media. Such media can be any available media that is accessible by the processing device 502, and includes both volatile and non-volatile media, and removable and non-removable media.

For example, the system memory 504 includes a non-volatile memory 508 such as a hard drive, and may also include a volatile memory 510, such as random access memory (RAM) and/or cache memory. The computer system 500 can further include other removable/non-removable, volatile/non-volatile computer system storage media.

The system memory 504 can include at least one program product having a set (e.g., at least one) of program modules that are configured to carry out functions of the embodiments described herein. For example, the system memory 504 stores various program modules that generally carry out the functions and/or methodologies of embodiments described herein. A module or modules 512, 514 may be included to perform functions related to control of the display 108, such as, for example, determining a target image based on in-vehicle, environmental, pre-programed, or external data and directing the display 108 (via, e.g., the controller 404) to drive one or more of the side-fire micro LEDs 210 to create the target image. The computer system 500 is not so limited, as other modules may be included depending on the desired functionality of the respective displays. As used herein, the term “module” refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality. For example, the module(s) can be configured via software, hardware, and/or firmware to cause a display (the display 108) to display an image, such as, for example, a vehicle status or a driver and/or passenger communication.

The processing device 502 can also be configured to communicate with one or more external devices 516 such as, for example, a keyboard, a pointing device, and/or any devices (e.g., a network card, a modem, vehicle ECUs, etc.) that enable the processing device 502 to communicate with one or more other computing devices. Communication with various devices can occur via Input/Output (I/O) interfaces 518 and 520.

The processing device 502 may also communicate with one or more networks 522 such as a local area network (LAN), a general wide area network (WAN), a bus network and/or a public network (e.g., the Internet) via a network adapter 524. In some embodiments, the network adapter 524 is or includes an optical network adaptor for communication over an optical network. It should be understood that although not shown, other hardware and/or software components may be used in conjunction with the computer system 500. Examples include, but are not limited to, microcode, device drivers, redundant processing units, external disk drive arrays, RAID systems, and data archival storage systems, etc. In some embodiments, the computer system 500 and/or the processing device 502 can receive information from one or more micro sensors (e.g., the sensor units 302), analyze said information, and send the information (raw, pre-processed, and/or post-processed) to one or more LEDs (e.g., the micro LEDs 210) and/or any other component of the vehicle 100.

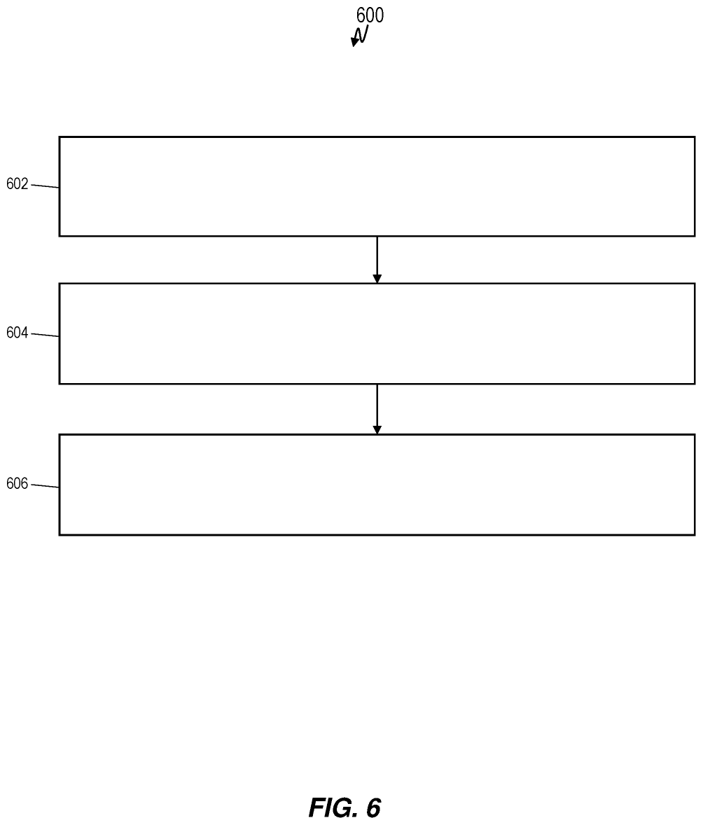

Referring now to FIG. 6, a flowchart 600 for a shaped micro reflector printing process for side-fire micro light-emitting diode (micro LED) displays is generally shown according to an embodiment. The flowchart 600 is described in reference to FIGS. 1 to 5 and may include additional steps not depicted in FIG. 6. Although depicted in a particular order, the blocks depicted in FIG. 6 can be rearranged, subdivided, and/or combined.

At block 602, the method includes forming a cartridge. In some embodiments, forming the cartridge includes forming a release layer on a substrate, forming a shaped micro reflector on the release layer, the shaped micro reflector having tapered sidewalls, and forming a reflective layer over the shaped micro reflector and the release layer.

At block 604, the method includes bonding the cartridge to a display substrate using a bonding layer positioned between the reflective layer and the display substrate. In some embodiments, the cartridge is flipped prior to bonding to the display substrate.

At block 606, the method includes removing the release layer of the cartridge, thereby separating the substrate from the display substrate. In some embodiments, removing the release layer includes at least one of exposing the release layer to UV radiation and exposing the release layer to thermal energy.

In some embodiments, the release layer includes at least one of an ultraviolet (UV) curable material and a thermally curable material.

In some embodiments, the reflective layer is conformally deposited over the shaped micro reflector and the release layer. In some embodiments, the reflective layer is conformally deposited to a thickness of between 5 nanometers and 3 microns.

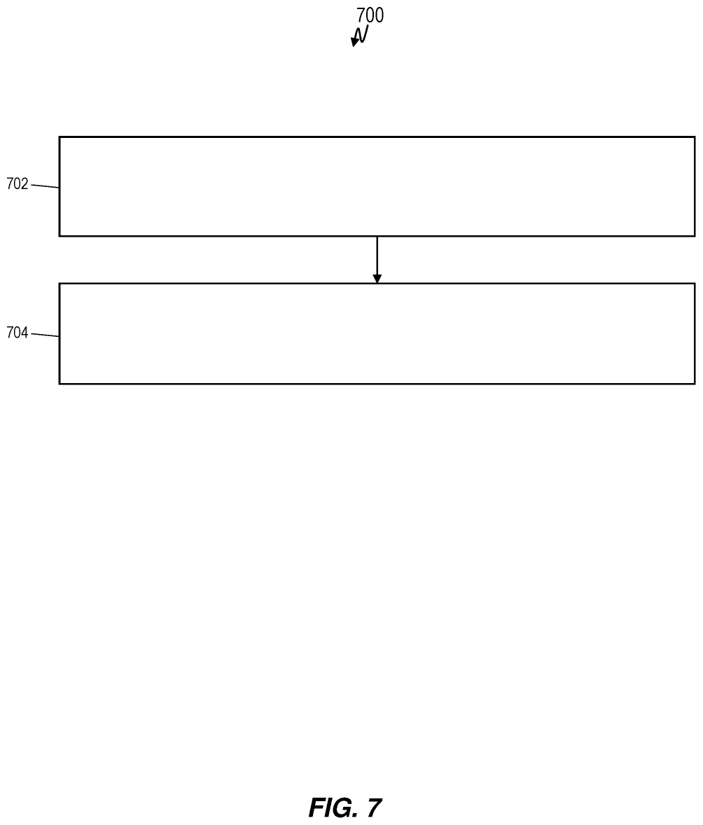

Referring now to FIG. 7, a flowchart 700 for a shaped micro reflector printing process for side-fire micro light-emitting diode (micro LED) displays is generally shown according to an embodiment. The flowchart 700 is described in reference to FIGS. 1 to 5 and may include additional steps not depicted in FIG. 7. Although depicted in a particular order, the blocks depicted in FIG. 7 can be rearranged, subdivided, and/or combined.

At block 702, the method includes forming a side-fire micro light-emitting diode on a surface of a display substrate. In some embodiments, the side-fire micro light-emitting diode is coated with a first reflective layer such that light is emitted from an uncoated sidewall.

At block 704, the method includes forming a shaped micro reflector coated with a second reflective layer on the display substrate. In some embodiments, the shaped micro reflector is adjacent to the side-fire micro light-emitting diode. In some embodiments, the shaped micro reflector includes a tapered sidewall positioned to redirect, via reflection against the second reflective layer, light from the uncoated sidewall of the side-fire micro light-emitting diode from an emitted angle to a reflection angle. In some embodiments, the second reflective layer is formed directly on opposite sidewalls and a bottommost surface of the shaped micro reflector.

In some embodiments, the tapered sidewall includes a degree of taper as measured with respect to the surface of the display substrate of between −90 and 90 degrees, where zero degrees of taper is orthogonal to the surface of the display substrate.

In some embodiments, the shaped micro reflector includes a taper of 30 to 60 degrees.

In some embodiments, a topmost surface opposite the bottommost surface of the shaped micro reflector is not coated with the second reflective layer.

In some embodiments, the uncoated sidewall of the side-fire micro light-emitting diode directly faces the tapered sidewall of the shaped micro reflector.

In some embodiments, a tracer formed on the display substrate. In some embodiments, the shaped micro reflector and second reflective layer are formed on the tracer.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A method comprising:
forming a cartridge, wherein forming the cartridge comprises:
forming a release layer on a substrate;
forming a shaped micro reflector on the release layer, the shaped micro reflector comprising tapered sidewalls; and
forming a reflective layer over the shaped micro reflector and the release layer;
bonding the cartridge to a display substrate using a bonding layer positioned between the reflective layer and the display substrate; and
removing the release layer of the cartridge, thereby separating the substrate from the display substrate.

2. The method of claim 1, wherein the release layer comprises at least one of an ultraviolet (UV) curable material and a thermally curable material.

3. The method of claim 1, wherein the reflective layer is conformally deposited over the shaped micro reflector and the release layer.

4. The method of claim 2, wherein the reflective layer is conformally deposited to a thickness of between 5 nanometers and 3 microns.

5. The method of claim 1, wherein the cartridge is flipped prior to bonding to the display substrate.

6. The method of claim 1, wherein removing the release layer comprises at least one of exposing the release layer to UV radiation and exposing the release layer to thermal energy.

7. The method of claim 1, further comprising forming a side-fire micro light-emitting diode on a surface of a display substrate, the side-fire micro light-emitting diode coated such that light is emitted from an uncoated sidewall.

8. A display unit comprising:
a side-fire micro light-emitting diode on a surface of a display substrate, the side-fire micro light-emitting diode coated with a first reflective layer such that light is emitted from an uncoated sidewall; and
a shaped micro reflector coated with a second reflective layer on the display substrate, the shaped micro reflector adjacent to the side-fire micro light-emitting diode, the shaped micro reflector comprising a tapered sidewall positioned to redirect, via reflection against the second reflective layer, light from the uncoated sidewall of the side-fire micro light-emitting diode from an emitted angle to a reflection angle, the second reflective layer formed directly on opposite sidewalls and a bottommost surface of the shaped micro reflector.

9. The display unit of claim 8, wherein the tapered sidewall comprises a degree of taper as measured with respect to the surface of the display substrate of between −90 and 90 degrees, wherein zero degrees of taper is orthogonal to the surface of the display substrate.

10. The display unit of claim 9, wherein the shaped micro reflector comprises a taper of 30 to 60 degrees.

11. The display unit of claim 8, wherein a topmost surface opposite the bottommost surface of the shaped micro reflector is not coated with the second reflective layer.

12. The display unit of claim 8, wherein the uncoated sidewall of the side-fire micro light-emitting diode directly faces the tapered sidewall of the shaped micro reflector.

13. The display unit of claim 8, further comprising a tracer formed on the display substrate.

14. The display unit of claim 13, wherein the shaped micro reflector and second reflective layer are formed on the tracer.

15. A method comprising:
forming a side-fire micro light-emitting diode on a surface of a display substrate, the side-fire micro light-emitting diode coated with a first reflective layer such that light is emitted from an uncoated sidewall; and
forming a shaped micro reflector coated with a second reflective layer on the display substrate, the shaped micro reflector adjacent to the side-fire micro light-emitting diode, the shaped micro reflector comprising a tapered sidewall positioned to redirect, via reflection against the second reflective layer, light from the uncoated sidewall of the side-fire micro light-emitting diode from an emitted angle to a reflection angle, the second reflective layer formed directly on opposite sidewalls and a bottommost surface of the shaped micro reflector.

16. The method of claim 15, wherein the tapered sidewall comprises a degree of taper as measured with respect to the surface of the display substrate of between −90 and 90 degrees, wherein zero degrees of taper is orthogonal to the surface of the display substrate.

17. The method of claim 16, wherein the shaped micro reflector comprises a taper of 30 to 60 degrees.

18. The method of claim 15, wherein a topmost surface opposite the bottommost surface of the shaped micro reflector is not coated with the second reflective layer.

19. The method of claim 15, wherein the uncoated sidewall of the side-fire micro light-emitting diode directly faces the tapered sidewall of the shaped micro reflector.

20. The method of claim 15, further comprising a tracer formed on the display substrate, wherein the shaped micro reflector and second reflective layer are formed on the tracer.
